(19) United States
(12) Patent Application Publication
(10) Pub. No.: US 2008/0105379 A1
(43) Pub. Date: May 8, 2008

(54) Plasma processing apparatus

(75) Inventors: Naoko Yamamoto, Osaka-shi (JP); Syuichi Kitamura, Sakurai-shi (JP); Koji Murakami, Souraku-gun (JP); Riki Tomoyoshi, Tenri-shi (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 11/897,231

(22) Filed: Aug. 29, 2007

(30) Foreign Application Priority Data
Aug. 31, 2006 (JP) 2006-235895

(51) Int. Cl. C23C 16/50; C23F 1/08

(52) U.S. Cl. 156/345.43; 118/723 E

(57) ABSTRACT

A plasma processing apparatus according to the present invention includes at least a pair of elongated electrode units which are faced to each other, each electrode unit including an elongated conductive member extending in a longitudinal direction, an elongated dielectric member which is provided on the conductive member in the longitudinal direction, and a fastening member for fastening the conductive member and the dielectric member to each other, wherein the fastening member fastens the conductive member and the dielectric member to each other such that they can displace with respect to each other in the event of the occurrence of thermal expansions of the conductive member and the dielectric member.

### CROSS-REFERENCE TO RELATED APPLICATION

This application is related to Japanese Patent Application No. 2006-235895 filed on Aug. 31, 2006, whose priority is claimed under 35USC § 119, the disclosure of which is incorporated by reference in its entirety.

### BACKGROUND OF THE INVENTION

1. Field of the Invention

The present invention relates to a plasma processing apparatus for forming thin films, applying processing to thin films and performing surface treatments and, more particularly, relates to a plasma processing apparatus for creating a plasma and applying plasma processing to substrates.

2. Description of the Related Art

Plasma processing apparatuses for performing various types of plasma processing such as etching, film formation, ashing and surface treatments have been used for fabricating various types of electronic devices such as semiconductor devices, flat panel displays and solar cells. Particularly, devices such as flat panel displays and thin-film solar cells which employ thin-film amorphous silicon, among electronic devices as described above, have been formed to include larger-sized processed components such as substrates having sizes of 2 m or more at their sides, in order to increase the sizes of the devices and to reduce the fabrication costs. Along therewith, plasma processing apparatus have been increased in size.

Most of plasma processing apparatuses employs high-frequency power supplies having frequencies in the RF range or the VHF range, as power supplies for creating a plasma, in view of processing speed or processing quality. For example, a plasma processing apparatus for processing substrates having a length of 2 m at a side thereof requires electrodes having an appropriate area with a length greater than 2 m at least at one of its sides.

Such a plasma processing apparatus has conventionally utilized a plasma under a reduced pressure. However, in recent years, plasma processing apparatuses which perform plasma processing under an atmospheric pressure or pressures near the atmospheric pressure have come into practical use. Under the atmospheric pressure or the pressure near the atmospheric pressure, such a plasma processing apparatus requires no vacuum chamber, which enables reduction of the size of the apparatus. Further, the density of active plasma species can be increased, which can increase the processing speed. Further, there is provided the advantage that the processing time per single to-be-processed substrate can be made substantially equal to the plasma processing time, depending on a structure of the apparatus. On the other hand, if the applied electric power is increased for increasing the processing speed, this will induce arc discharge, in cases where the metal electrode portions are exposed at surfaces. Therefore, the surfaces of the metal electrodes are generally coated with solid dielectric members. If a high voltage is applied to a pair of opposed metal electrodes which are coated with solid dielectric members, this will create a plasma between the solid dielectric members. At this time, if a magnitude of a gap between the metal electrodes and the solid dielectric members covering the surfaces of the metal electrodes is equal to or more than several tens of micrometers, this may induce abnormal discharge within the gap.

To address the aforementioned problem, there has been known a dielectric-member supporting method for eliminating the gap, in order to prevent the occurrence of abnormal discharge within the gap between the metal electrodes and the solid dielectric members (refer to JP-A No. 2005-19150, for example). Also, it is possible to employ a method for embedding an adhesive agent in a gap between the metal electrodes and the dielectric members, but there are a difference in linear expansion coefficient and a difference in the amount of temperature increase between the metal and the dielectric material, which makes it difficult to equalize the amounts of their thermal expansions to each other and also may cause exfoliation at a portion at which they are attached to each other. On the contrary, there has been known a method for attaching the metal electrodes and the dielectric members to each other using an adhesive agent capable of absorbing the difference in thermal expansion between the metal electrodes and the dielectric members, in order to absorb the difference in thermal expansion therebetween (refer to JP-A No. 2004-288452, for example).

However, in cases of employing elongated electrodes having a length of 1 m or more at one side thereof, there is induced the problem of warpage of the electrodes caused by the difference in the amount of thermal expansion among the members constituting the electrodes. More specifically, the electrodes are constituted by a plurality of members with different linear expansion coefficients, such as solid dielectric materials and solid conductive materials. Accordingly, during operations, if the temperature of the electrodes is changed by cooling through a cooling water or heating through the created plasma, this will induce warpage of the electrodes due to the difference in linear expansion coefficient and the difference in the amount of thermal expansion due to the temperature difference, among the different materials and the different members made of the same material, unlike during assembling of the electrodes. If excessive warpage occurs, in cases where a high-pressure plasma such as an atmospheric-pressure plasma is used, there is induced the problem that a gap between the electrodes is varied by a nonnegligible amount in a longitudinal direction since the magnitude of the gap between the electrodes is several millimeters and is extremely small, which exerts influences on processing and the like.

### SUMMARY OF THE INVENTION

The present invention was made in view of the aforementioned circumstances and aims at providing a plasma processing apparatus capable of suppressing warpage of electrodes caused by a change of the temperature of the electrodes for mostly eliminating an influence thereof on the magnitude of a gap between the electrodes.

According to the present invention, there is provided a plasma processing apparatus including at least a pair of elongated electrode units which are faced to each other for creating a plasma within a process gas when a high-frequency voltage is applied thereto, each electrode unit including an elongated conductive member extending in a longitudinal direction, an elongated dielectric member provided on the conductive member in the longitudinal direction, and a fastening member for fastening the conductive member and the dielectric member to each other, wherein the fastening member fastens the conductive member and the dielectric member to each other such that they can displace with respect to each other in the event of the occurrence of thermal expansions of the conductive member and the dielectric member.

With the present invention, the fastening member fastens the conductive member and the dielectric member to each other such that they can displace with respect to each other in the event of the occurrence of thermal expansions of the conductive member and the dielectric member, which can suppress the warpage of the electrode units caused by the difference in the amount of thermal expansion among the members constituting the electrode units, thereby enabling plasma processing with high uniformity.

### BRIEF DESCRIPTION OF THE DRAWINGS

FIG. 1 is a main-part cross-sectional view of a plasma processing apparatus according to an embodiment of the present invention;

FIG. 2 is a main-part perspective view of the plasma processing apparatus according to the embodiment of the present invention;

FIG. 3 is an entire structural view of the plasma processing apparatus according to the embodiment of the present invention;

FIG. 4 is an explanation view illustrating a change of a gap between electrode portions in a conventional plasma processing apparatus;

FIG. 5 is an explanation view illustrating the change of the gap between the electrode portions in the conventional plasma processing apparatus;

FIG. 6 is an enlarged view of a fastening portion according to the embodiment of the present invention;

FIG. 7 is an enlarged view of the fastening portion according to the embodiment of the present invention;

FIG. 8 is a top view of the electrode portions according to the embodiment of the present invention;

FIG. 9 is an enlarged view of the fastening portion according to the embodiment of the present invention;

FIG. 10 is an enlarged view of the fastening portion according to the embodiment of the present invention;

FIG. 11 is a top view illustrating an exemplary modification of the electrode portions according to the embodiment of the present invention;

FIG. 12 is a graph illustrating changes of amounts of thermal expansions with time, according to the embodiment of the present invention; and

FIG. 13 is a circuit diagram illustrating an electric circuit according to the embodiment of the present invention.

### DESCRIPTION OF THE PREFERRED EMBODIMENTS

A plasma processing apparatus according to the present invention includes at least a pair of elongated electrode units which are faced to each other for creating a plasma within a process gas when a voltage with a high frequency is applied thereto, each electrode unit including an elongated conductive member extending in a longitudinal direction, an elongated dielectric member which is provided on the conductive member in the longitudinal direction, and a fastening member for fastening the conductive member and the dielectric member to each other, wherein the fastening member fastens the conductive member and the dielectric member to each other such that they can displace with respect to each other in the event of the occurrence of thermal expansions of the conductive member and the dielectric member.

The pair of electrode units according to the present invention may be structured to create a plasma in a process gas when a voltage having a high frequency is applied thereto.

The conductive member, which mainly constitutes a plasma-creating electrode, may be made of a metal with a high conductivity, such as aluminum, stainless steel or cupper. In this case, the electrodes are sized to have a length of 2 to 3 m, a width of 30 to 50 mm and a thickness of 10 to 20 mm, for example.

The dielectric member may be utilized as a protective member covering an electrode surface for preventing the occurrence of arc discharge between plasma-creating electrodes or a supporting member for supporting the plasma-creating electrodes.

The dielectric member may be mainly made of a material having a high permittivity and a high heat conductivity, such as alumina or aluminum nitride.

Further, the fastening member may be constituted by a common bolt, washer, collar, nut, and the like. As the material thereof, it is possible to select properly a material having an appropriate conductivity and an appropriate permittivity.

The fastening member may be adapted to fasten the conductive member and the dielectric member to each other such that they can displace with respect to each other in the longitudinal direction.

One of the conductive member and the dielectric member may be structured to have an oval hole having a greater diameter parallel to the longitudinal direction, so that the fastening member fastens the electrode and the dielectric member to each other through the oval hole.

The fastening member preferably includes a metal bolt and a washer made of an organic material having lubricating property. In this case, as the organic material, it is possible to employ a slippery material, such as Teflon (trademark) or PEEK. The use of such a washer made of an organic material offers the effect of allowing the bolt and the washer to displace with each other.

Further, one of the conductive member and the dielectric member may be formed to have three or more oval holes having a greater diameter parallel to the longitudinal direction so that the oval holes are arranged in the longitudinal direction, the fastening member may be adapted to fasten the electrode and the dielectric member to each other through the oval holes, and the oval holes may be formed such that the oval hole at a center position is smallest in greater diameter, and the other oval holes are gradually increased in greater diameter with a distance from the center position.

Hereinafter, the present invention will be described, with reference to an embodiment illustrated in the drawings. However, the present invention is not limited to the following embodiment.

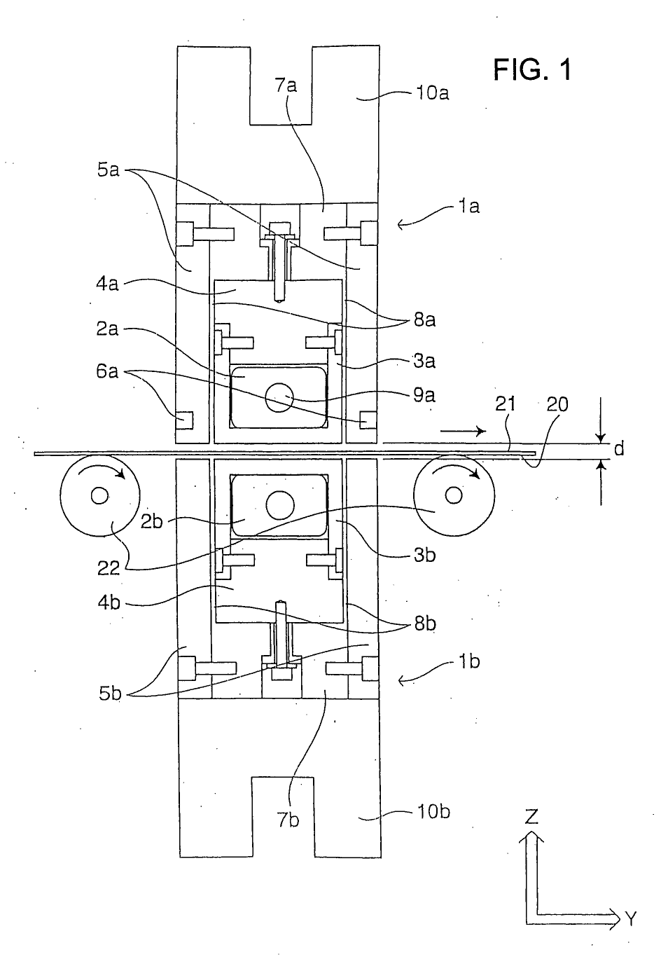

FIG. 1 is a main-part cross-sectional view of a plasma processing apparatus according to an embodiment of the present invention. The plasma processing apparatus according to the embodiment is a plasma processing apparatus for applying processing to substrates in an in-line manner or for applying processing to sheet-type or roll-type objects to be processed. There is illustrated, in FIG. 1, a cross-sectional area of a to-be-processed substrate along a direction of transferring (a cross-sectional area along the XY direction).

As illustrated in FIG. 1, the plasma processing apparatus is of an opposed-electrode type and includes a pair of electrode units (hereinafter, referred to as electrode portions) 1a and 1b which are opposed to each other. The electrode portions 1a and 1b are placed above a to-be-processed surface 21 of a to-be-processed substrate 20 in a vertical direction (in a positive side in a direction of a Z axis) and below the to-be-processed surface 21 of the to-be-processed substrate 20 in the vertical direction (in a negative side in the direction of the Z axis), respectively. Further, a gap (interval) d between the electrode portion 1a and the electrode portion 1b is set to be an appropriate value in the range of 3 to 10 mm.

Next, a structure of the electrode portions 1a and 1b will be described, in detail.

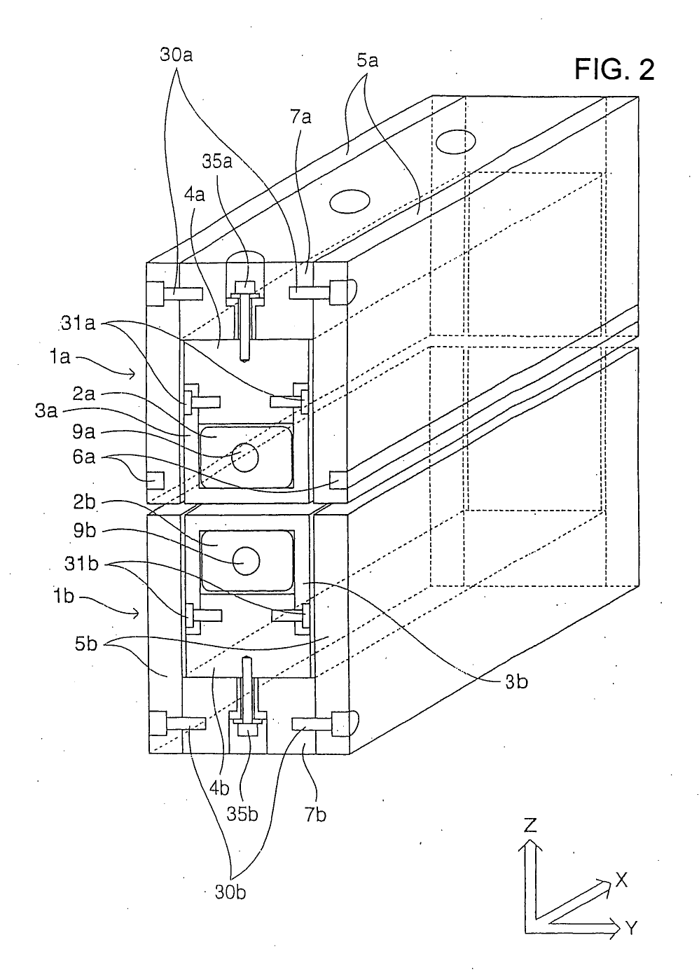

FIG. 2 is a perspective view of the electrode portions 1a and 1b. Note that the electrode portions 1a and 1b are placed symmetrically with respect to an XY plane, except portions thereof.

As illustrated in FIG. 1 and FIG. 2, the electrode portions 1a and 1b include metal electrodes 2a and 2b, dielectric members 3a and 3b formed to have substantially a U-shaped cross-sectional area such that they cover the metal electrodes 2a and 2b, dielectric members 4a and 4b formed to have substantially a T-shaped cross-sectional area which encloses the metal electrodes 2a and 2b in combination with the dielectric members 3a and 3b, metal supporting portions (hereinafter, referred to as metal electrodes) 7a and 7b which are provided on upper and lower portions of the dielectric members 4a and 4b and include gas-flow paths provided inside thereof, and dielectric members 5a and 5b having substantially an I-shaped cross-sectional area which are provided at opposite sides of the metal electrodes 7a and 7b.

Further, the electrode portion 1a includes metal electrodes 6a embedded in concave portions in side surfaces of the dielectric members 5a, unlike the electrode portion 1b.

Inside the metal electrodes 2a and 2b, there are provided cooling-water flow paths 9a and 9b for cooling the metal electrodes 2a and 2b and the dielectric members 3a and 3b. The respective flow paths are connected at their opposite ends to a cooling-water introduction port and a cooling-water ejection port, which are not illustrated.

In the present embodiment, metal electrodes having a greater length and a smaller width are employed as exemplary metal electrodes, and the metal electrodes 2a and 2b have a width of 33 mm in a direction of a Y axis, a height of 15 mm in the direction of the Z axis and a length of 2250 mm in a direction of a X axis. Further, the dielectric members 3a and 3b are formed to have substantially a U-shaped cross-sectional area sized to have a width of 42 mm, a height of 30 mm and a length of 2350 mm. Further, the dielectric members 4a and 4b are sized to have a width of 42 mm, a height of 30 mm and a length of 2350 mm. The dielectric members 5a and 5b are sized to have a width of 8 mm, a height of 65 mm and a length of 2350 mm. The metal electrodes 6a are sized to have a width of 4 mm, a height of 4 mm and a length of 2400 mm.

In this case, the metal electrode 2a is covered at its four surfaces in the longitudinal direction with the dielectric member 3a and the dielectric member 4a, in order to prevent the occurrence of arc discharge between the metal electrodes 2a and 2b. The dielectric members 5a are provided between the metal electrodes 6a and the metal electrode 2a. Further, the dielectric member 4a is provided between the metal electrode 7a and the metal electrode 2a, in order to prevent the occurrence of arc discharge, similarly to the aforementioned structure. The electrode portion 1b also has the same structure.

The metal electrodes 2a, 2b, 7a and 7b are made of materials having high conductivities, such as aluminum (Al) or stainless steel (SUS) and have been subjected, at their surfaces, to surface treatment such as alumite or alumina spraying, as required, in order to prevent the occurrence of arc discharge due to the occurrence of gaps between their surfaces and the dielectric members and, also, in order to prevent the corrosion caused by plasma and the like.

The dielectric members 3a, 3b, 4a, 5a and 5b are made of dielectric materials having high permittivities and high heat conductivities, such as alumina and aluminum nitride.

Further, as illustrated in FIG. 1, there are provided gaps 8a and 8b having a magnitude of about 1 mm, between the dielectric members 5a and 5b and the dielectric members 3a and 3b, which allows a process gas to be introduced into the gaps 8a and 8b through gas introduction ports, not illustrated, which are provided through supporting members 10a and 10b made of a metal and through the metal electrodes 7a and 7b.

As illustrated in FIG. 2, bolts 31a (31b) made of a dielectric material are screwed into bolt insertion holes (threaded holes) in the electrode portion 1a (1b), so that the dielectric member 3a (3b) is secured to the dielectric member 4a (4b). Metal bolts 30a (30b) are screwed into bolt insertion holes (threaded holes), so that the metal electrode 7a (7b) is secured to the dielectric members 5a (5b) at the opposite sides thereof. Further, a metal bolt 35a (35b) is screwed into a bolt insertion hole (threaded hole) so that the electrode 7a (7b) is secured to the dielectric member 4a (4b).

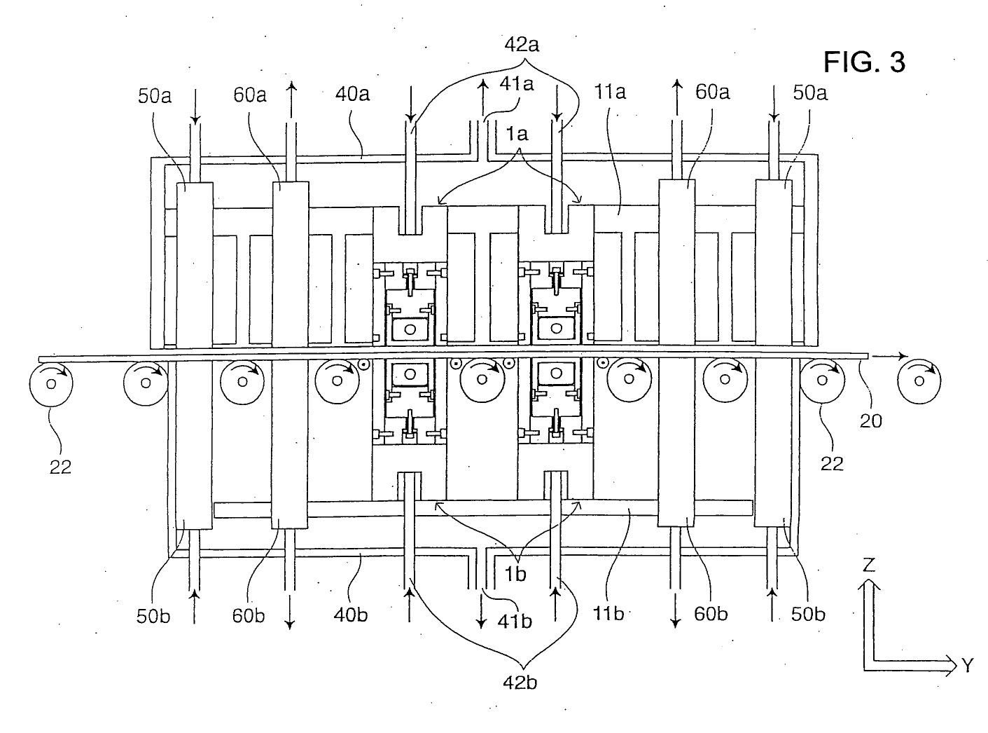

Next, with reference to FIG. 3, plasma processing using the electrode portions 1a and 1b will be described.

The plasma processing apparatus of FIG. 3 includes two pairs of electrode portions 1a and 1b. The electrode portions 1a and 1b, gas curtain portions 50a and 50b and internal exhaust portions 60a and 60b are secured to electrode frames 11a and 11b. There are cabinets 40a and 40b outside the electrode frames 11a and 11b, and exhaust is performed by a pump which is not illustrated, through exhaust ports 41a and 41b, such that there is a negative pressure within the cabinets 40a and 40b. In this case, the gas curtain portions 50a and 50b have a slit-shaped ejection port having a greater length in the X direction at a side of a substrate-transfer surface and have a function of ejecting gas outwardly in a curtain manner from the ejection port for separating the gas atmosphere within the cabinets 40a and 40b from external air.

Further, there is external air flowing into the cabinets during transferring substrates and, also, there are down flows outside the cabinets in cases where the apparatus is installed in a clean room, and these air flows impinge the substrates and try to intrude into the cabinets. In order to prevent this phenomenon, the gas curtain portions are installed. The internal exhaust portions are for exhausting process gas, for exhausting gases during plasma creation and after reactions and also for exhausting external air from the outside of the cabinets which could not be prevented from intruding into the cabinets through the gas curtain portions, without causing it to enter the electrode portions.

Further, a process gas formed by mixing He (=10 SLM), N₂ (=5 SLM) and air (=0.08 SLM) with one another, for example, is continuously introduced into the gaps 8a and 8b (FIG. 1) through the gas introduction ports 42a and 42b for several tens of seconds, under an atmospheric pressure or under a presser near the atmospheric pressure, to replace the atmosphere around the electrode portions 1a and 1b with an atmosphere having a composition ratio near that of the process gas, even under the atmospheric pressure or under the pressure near the atmospheric pressure.

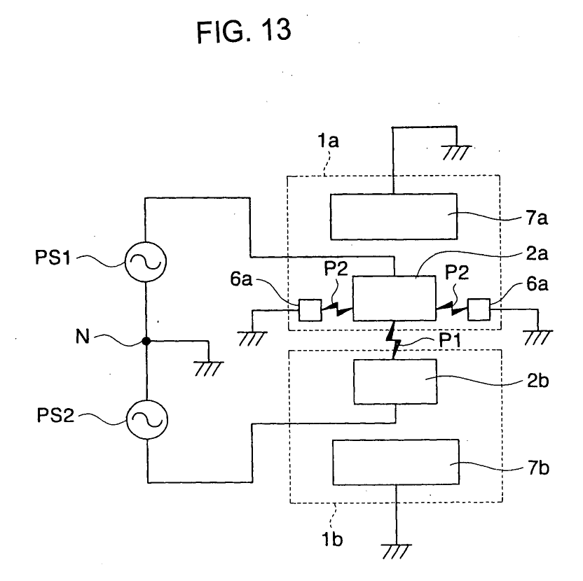

Thereafter, cooling water is flowed through the cooling-water flow paths 9a and 9b (FIG. 1 and FIG. 2) in the metal electrodes 2a and 2b at a flow rate of 10 SLM. Further, as illustrated in FIG. 13, voltages having a frequency of 30 kHz, a peak-to-peak voltage Vpp of 7.5 kV and opposite phases are applied from high-frequency power supplies PS1 and PS2 to the metal electrodes 2a and 2b, which causes a voltage having a peak-to-peak voltage Vpp of 15 kV to be applied between the metal electrodes 2a and 2b. Note that a point N at which the power supplies PS1 and PS2 are connected to each other is grounded and is connected to the metal electrodes 6a and the metal electrodes 7a and 7b.

Accordingly, an inter-electrode voltage having a peak-to-peak voltage Vpp of 7.5 kV is applied to a gap portion between the metal electrode 2a and the metal electrode 6a. This gap portion is smaller than a gap portion between the metal electrodes 2a and 2b as illustrated in FIG. 1 and, therefore, there is a greater electric field in this gap portion, which causes a seed plasma P2 to be created earlier. Next, a main plasma P1 is created in the gap portion between the metal electrodes 2a and 2b. Namely, the seed plasma P2 has a function of inducing the formation of the main plasma P1.

After the creation of these plasmas P1 and P2, the to-be-processed substrate 20 with a size of 2100 mm*2400 mm*0.7 mm on which organic materials such as a resist and polyimide have been deposited and patterns have been formed is penetrated through the main plasma P1 in an in-line manner using transferring rollers 22 between the electrode portions 1a and 1b, as illustrated in FIG. 1 and FIG. 3. This enables the plasma processing apparatus to apply, to the to-be-processed substrate 20, resist-ashing processing, hydrophilic processing such as removing the polyimide film and organic materials from the glass substrate portion, and the like.

The plasma-processing capacity of the aforementioned electrodes, such as the amount of ashing, is determined by a type of the process gas, a composition ratio of the process gas, a total flow rate of the process gas, a frequency of high-frequency power supplies, an electricity consumed by the main plasma, a length of the metal electrodes 2a and 2b in a direction of transferring, a magnitude d of the gap between the electrode portions, a speed at which the to-be-processed substrate is transferred, a velocity of the flow of the process gas, and the like.

Further, according to the processing capacity required for the plasma processing, such as the amount of ashing, the plurality of pairs of electrode portions 1a and 1b can be placed in the direction of transferring of the to-be-processed substrate, as illustrated in FIG. 3, or the width of the metal electrodes 2a and 2b in the electrode portions 1a and 1b can be changed.

On the other hand, in the plasma processing apparatus for performing the aforementioned processing, the dielectric member 3a in the electrode portion 1a is directly exposed, at its side of the to-be-processed substrate surface, to the main plasma P1, as illustrated in FIG. 1 and FIG. 2, which causes heat of the plasma to be introduced into the dielectric member 3a, thereby increasing the temperature of the dielectric member 3a.

Accordingly, the dielectric member 3a is designed such that its surface opposite from the to-be-processed surface is contacted with the metal electrode 2a, so that the cooling water flowing within the metal electrode 2a depletes heat introduced from the plasma into the dielectric member 3a.

The electrode portions 1a and 1b are generally assembled in a room which is controlled in temperature to within the range of 20 to 25 degree C. If a voltage is continuously applied between the electrode portions 1a and 1b to create a plasma continuously, this will raise the temperatures of the dielectric member 4a and the metal electrode 7a to above a room temperature. In this case, the metal electrode 7a has a linear expansion coefficient higher than that of the dielectric member 4a and, therefore, the amount of thermal expansion of the metal electrode 7a is greater than that of the dielectric member 4a. On the other hand, if only the cooling water is continuously flowed through the electrodes without applying a voltage between the electrodes, this will decrease the temperatures of the dielectric member 4a and the metal electrode 7a to below the room temperature, thereby causing them to contract, since the temperature of the cooling water is lower than the room temperature by about 5 to 15 degree C. As a result, the metal electrode 7a is contracted by an amount greater than the amount of the contraction of the dielectric member 4a.

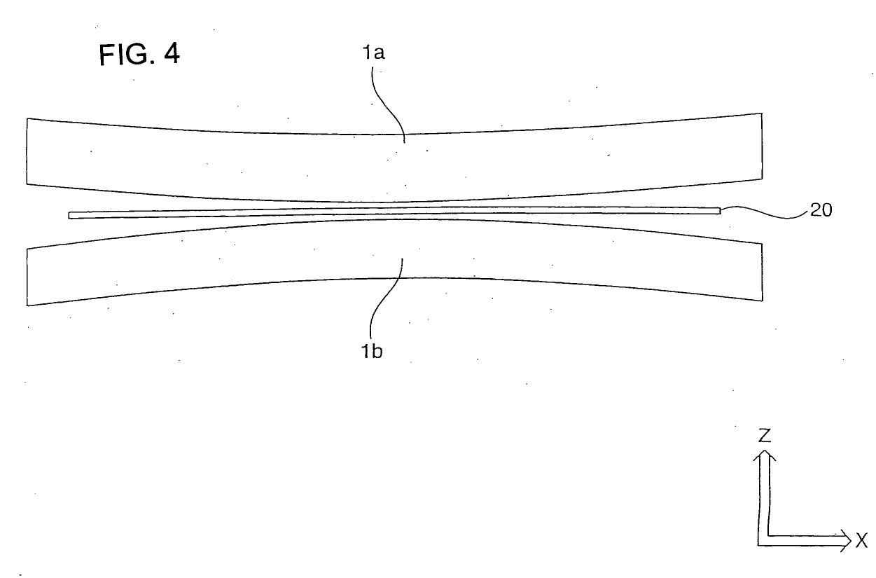

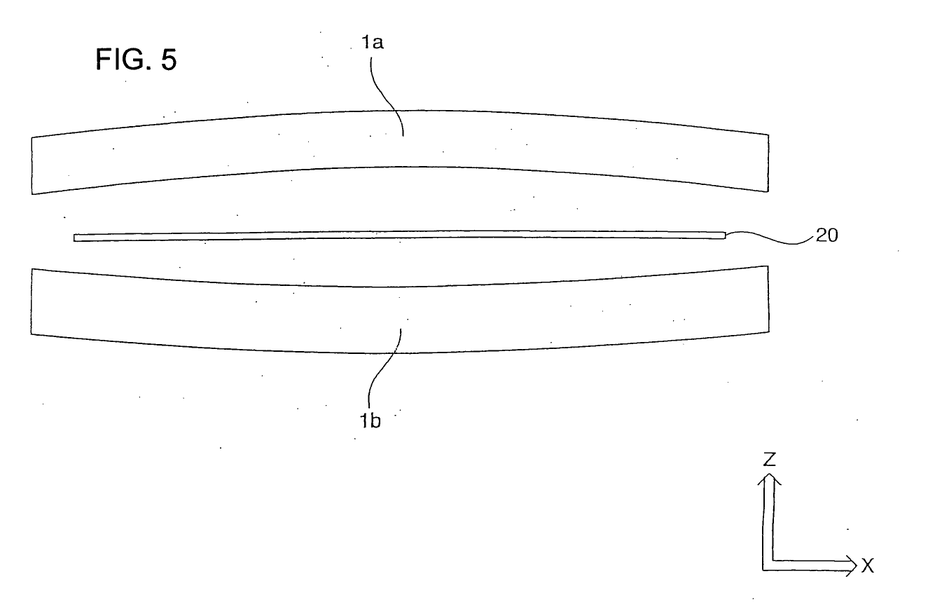

In this case, when the dielectric member 4a and the metal electrode 7a have been completely fastened and secured to each other with bolts through assembling, the electrode portion 1a is warped in the positive direction in the Z direction when it expands and also is warped in the negative direction in the Z direction when it contracts, for example, due to a bimetal phenomenon. This also applies to the electrode portion 1b and, therefore, the gap d between the electrodes is changed with a change of the temperature of the electrode portions 1a and 1b, as illustrated in FIG. 4 or FIG. 5.

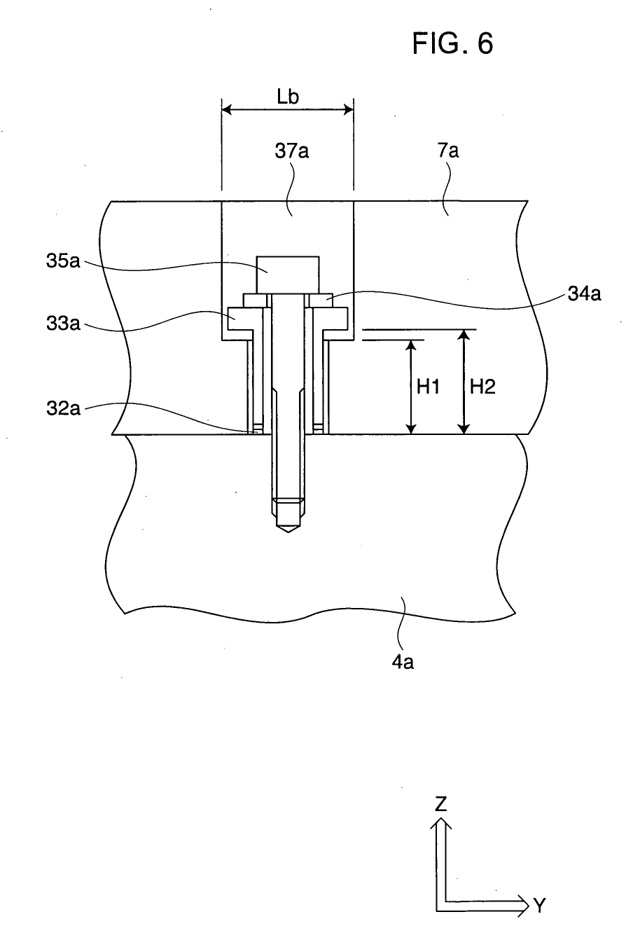

Further, since the electrode portions 1a and 1b are secured, at their opposite ends in the longitudinal direction, to end portions of the electrode frames 11a and 11b, the gap d between the electrode portions 1a and 1b is largely changed at its center portion as illustrated in FIG. 4, which causes the gap d to be varied in the X direction. In order to alleviate the phenomenon, there is provided a structure illustrated in FIGS. 6 to 11, in order to allow the dielectric members 4a and 4b and the metal electrodes 7a and 7b to displace with respect to each other in the event of the occurrence of thermal expansion or thermal contraction thereof.

FIG. 6 is an enlarged view illustrating the portion of the electrode portion 1a as illustrated in FIG. 1 and FIG. 2 at which the dielectric member 4a and the metal electrode 7a are fastened to each other.

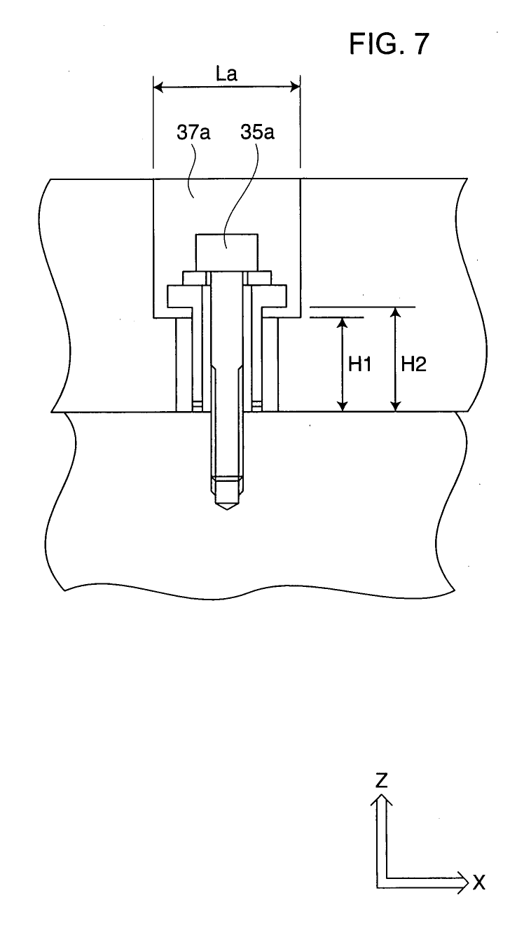

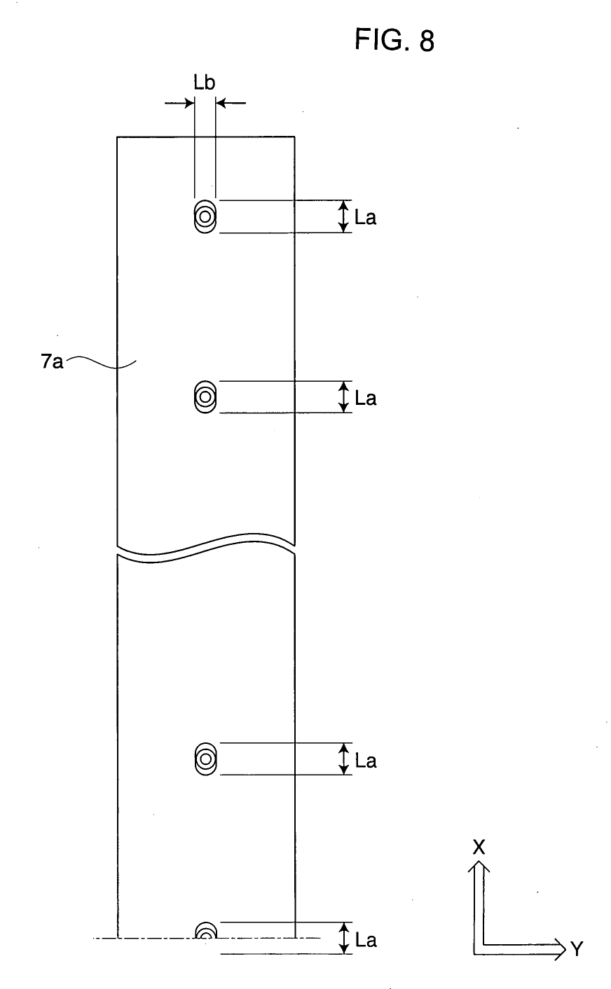

There are provided 19 positions at which the dielectric member 4a and the metal electrode 7a are fastened to each other, in serial in the X direction, as illustrated in FIG. 8. The structure of the fastening portion will be described, with reference to FIG. 6 and FIG. 7. The metal electrode 7a is provided with fastening spot-facing holes 37a, and the spot-facing holes 37a are long holes having a greater diameter La in the X direction as illustrated in FIG. 7 and also having a smaller diameter Lb in the Y direction as illustrated in FIG. 6. A fastening member constituted by a metal spacer 32a, a metal collar 33a, a metal washer 34a and a metal bolt 35a is inserted into each spot-facing hole 37a. A height H1 of the spot-facing portions in the metal electrode 7a and a height H2 of the step portions of the metal collars 33a satisfy a relationship of H2>H1, which actively provides a gap (clearance) therebetween, thereby enabling the dielectric member 4a and the metal electrode 7a to displace with respect to each other.

In order to satisfy the aforementioned relationship between the heights, the plurality of metal spacers 32a having a thickness in the range of about 0.03 to 0.10 mm are prepared, and the number of spacers is properly selected according to the relationship with the height of the step portions of the metal collars. The larger a magnitude (H2−H1) of a gap between the dielectric member 4a and the metal electrode 7a, the more easily they can displace with respect to each other. However, the larger the magnitude of the gap, the smaller the amount of heat transferred therethrough and, thus, the larger a temperature difference between the dielectric member 4a and the metal electrode 7a, which increases a difference in the amount of thermal expansion therebetween. Further, the larger the magnitude of the gap, the higher the tendency to induce discharge in the gap portion, which makes it impossible to perform temperature control. Accordingly, by setting the magnitude (H2−H1) of the gap to within the range of from 10 micrometers or more to 100 micrometers or less, it is possible to allow the dielectric member 4a and the metal electrode 7a to displace with respect to each other, while suppressing the reduction of the amount of heat transferred therebetween and also suppressing the occurrence of discharge in the gap.

Further, the spot-facing holes 37a in the metal electrode 7a are long holes having a greater diameter La in the X direction as illustrated in FIG. 7 and having a smaller diameter Lb in the Y direction as illustrated in FIG. 6, and the metal collars 33a have a circular-cylindrical shape, which causes the metal electrode 7a and the dielectric member 4a to be hardly displaced in the Y direction, but causes them to be displaced largely in the direction of the X axis (the longitudinal direction). Accordingly, even in the event of the occurrence of a length difference between the metal electrode 7a and the dielectric member 4a due to their contractions or expansions caused by cooling or heating, it is possible to absorb the length difference at the aforementioned displaceable portions, which can suppress the warpage caused by contractions or expansions to +−0.1 mm or less (FIG. 5 illustrates a change of the gap portion in the even of the occurrence of contraction).

The metal electrode 7a and the dielectric member 5a in the electrode portion 1a also can induce warpage due to the length difference therebetween which is caused by their contractions or expansions, at a portion at which they are coupled to each other, when they are cooled or heated to below or above the room temperature.

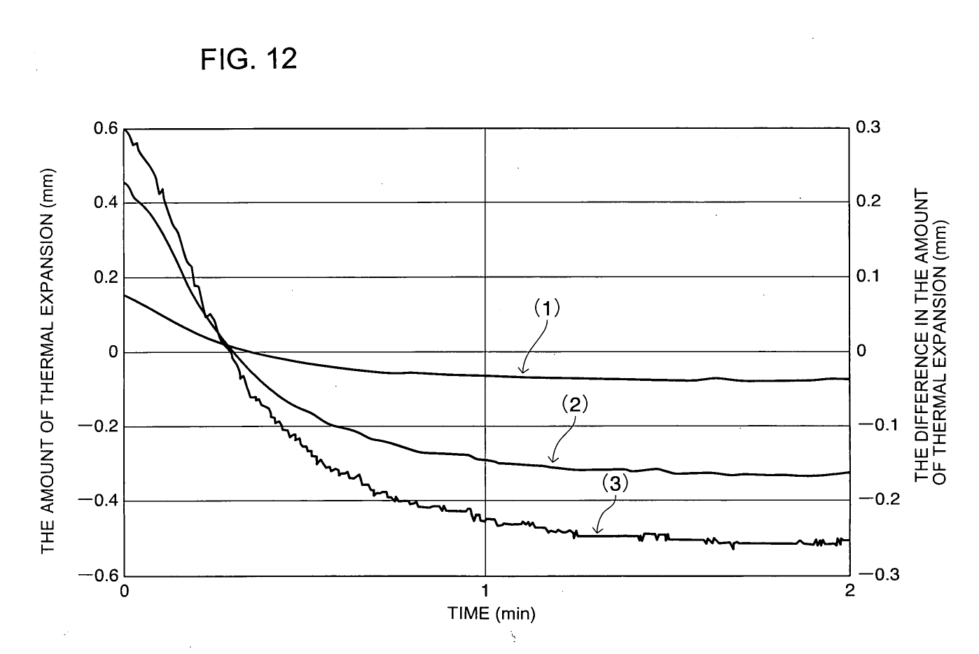

For example, FIG. 12 illustrates a graph illustrating a differences between a lengths of the metal electrode 7a and the dielectric member 5a at the room temperature and the lengths thereof after a plasma is created for a long time under a certain condition to raise the temperatures of the members in the electrode portions 1a and 1b to steady temperatures and then the discharge is stopped, in the case where the metal electrode 7a is formed from aluminum and the dielectric member 5a is formed from alumina.

A curve (1) illustrates the amount of thermal expansion of the dielectric member 5a, and a curve (2) illustrates the amount of thermal expansion of the metal electrode 7a. A curve (3) illustrates a difference between the amounts of thermal expansions illustrated in the curve (1) and the curve (2). This result reveals that the difference between the amounts of thermal expansions of the dielectric member 5a and the metal electrode 7a is +−0.3 mm. Accordingly, it is necessary only to provide long holes which enable the dielectric member 5a and the metal electrode 7a to displace by about +−0.5 mm or more.

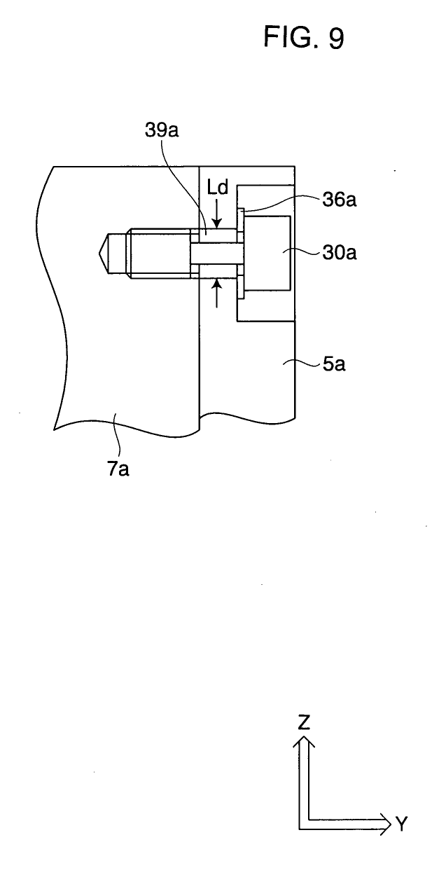

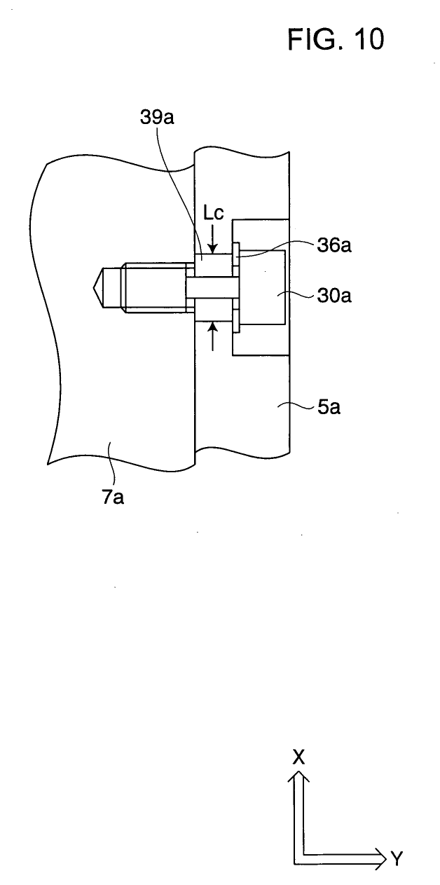

In this case, regarding a direction of warpage, since the electrodes are structured to have a shape symmetrical with respect to a ZX plane, the electrodes are not warped in the direction of the Y axis, but are warped by +−0.5 mm in the direction of the Z axis. In order to suppress the warpage, the metal bolts 30a illustrated in FIG. 2 are fastened with the structure illustrated in FIG. 9 and FIG. 10.

At a portion at which the metal electrode 7a and the dielectric member 5a are fastened to each other, there are provided metal bolts 30a having a partial constriction portion at the position corresponding to the washers 36a and the holes 39a in the dielectric member 5a.

Further, washers 36a made of an organic material such as Teflon (trademark) or PEEK are used with the metal bolts 30a. The bolt holes 39a provided in the dielectric members 5a are formed to be long holes having a greater diameter Lc in the direction of the X axis as illustrated in FIG. 10 and having a smaller diameter Ld in the direction of the Z axis as illustrated in FIG. 9. This realizes a structure which allows the metal electrode 7a and the dielectric members 5a to move with respect to each other (be displaceable), which can suppress the warpage of the electrode portion 2a in the direction of the Z axis to 0.1 mm or less. Note that the bolt holes 39a provided in the dielectric member 5a can be also formed to be circular-shaped holes having an appropriate diameter, not to be long holes, for offering the same effects. The metal bolts 35b and 30b can be fastened with the same structure as the aforementioned structure, which can also suppress the warpage of the electrode portion 2b.

As described above, with the structure according to the present embodiment, it is possible to suppress largely the warpage of the dielectric members even when elongated electrodes having a length of 1 m or more are employed, thereby providing a plasma processing apparatus capable of processing substrates having greater areas.

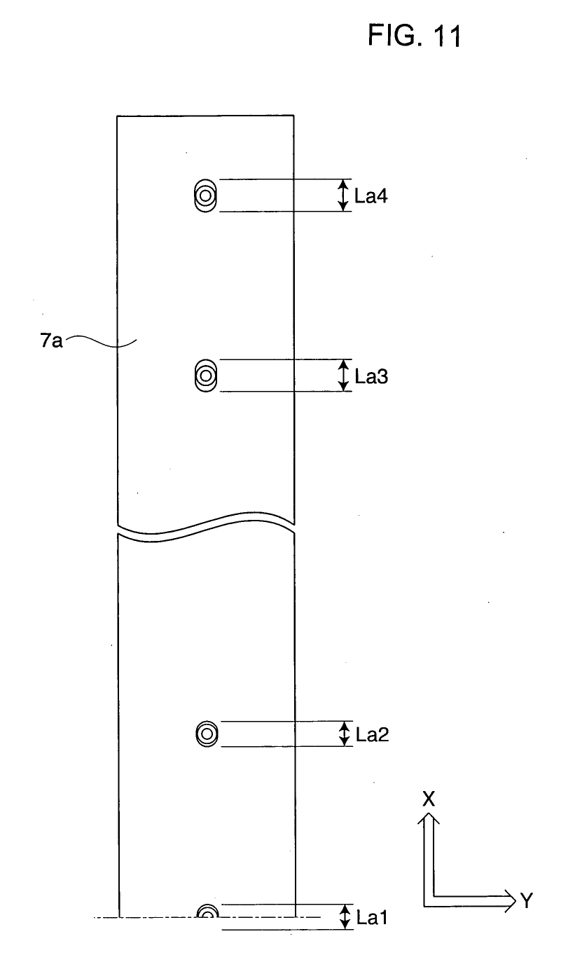

Further, in the case of forming long holes as illustrated in FIG. 8, these long holes are formed to have the same size (La*Lb) at any position. However, the long holes can also be formed to have greater diameters La1, La2, La3 and La4 in the directions toward the edges of the electrodes along the X axis, in such a way as to satisfy the relationship of La1<La2<La3<La4, as illustrated in FIG. 11. This can provide a structure capable of suppressing the displacement of the dielectric member 5a and the metal electrode 7a at a center of the electrodes as much as possible, absorbing the changes of their lengths caused by expansions or contractions due to the temperature change at the end portions of the electrodes, and also minimizing the positional displacement thereof in the X direction.

Note that in the present embodiment, there has been exemplified a case where the present invention is applied to an ashing apparatus, the present invention is not limited to the case, but can be applied to various types of plasma processing apparatuses such as etching apparatuses, surface-treatment apparatuses and film forming apparatuses. Further, the pressure under which plasma processing is performed is not limited to the atmospheric pressure, and the present invention can be applied to any elongated electrodes with lengths equal to or more than 1 m which have various temperature characteristics and made of various materials.

What is claimed is:

1. A plasma processing apparatus comprising at least a pair of elongated electrode units which are faced to each other for creating a plasma within a process gas when a voltage with a high frequency is applied thereto, each electrode unit comprising an elongated conductive member extending in a longitudinal direction, an elongated dielectric member which is provided on the conductive member in the longitudinal direction, and a fastening member for fastening the conductive member and the dielectric member to each other, wherein the fastening member fastens the conductive member and the dielectric member to each other such that they can displace with respect to each other in the event of the occurrence of thermal expansions of the conductive member and the dielectric member.

2. The plasma processing apparatus according to claim 1, wherein the elongated conductive member has a length of 2 to 3 m, a width of 30 to 50 mm and a thickness of 10 to 20 mm.

3. The plasma processing apparatus according to claim 1, wherein the fastening member fastens the conductive member and the dielectric member to each other such that they can displace with respect to each other in the longitudinal direction.

4. The plasma processing apparatus according to claim 2, wherein one of the conductive member and the dielectric member has an oval hole having a greater diameter parallel to the longitudinal direction, and the fastening member fastens the electrode and the dielectric member to each other through the oval hole.

5. The plasma processing apparatus according to claim 1, wherein the fastening member comprises a metal bolt and a washer made of an organic material having lubricating property.

6. The plasma processing apparatus according to claim 1, wherein one of the conductive member and the dielectric member has three or more oval holes each having a greater diameter parallel to the longitudinal direction, the oval holes are arranged in the longitudinal direction, the fastening member fastens the electrode and the dielectric member to each other through the oval holes, and the oval holes are formed such that the oval hole at a center position is smallest in greater diameter, and the other oval holes are gradually increased in greater diameter with the distance from the center position.

7. The plasma processing apparatus according to claim 1, wherein the fastening member comprises a bolt for coupling the conductive member and the dielectric member to each other and a cylindrical-shaped collar to which the bolt is fitted for coupling the conductive member and the dielectric member to each other such that they can displace.

8. The plasma processing apparatus according to claim 1, wherein the conductive member is greater than the dielectric member in linear expansion coefficient.

9. The plasma processing apparatus according to claim 1, wherein the conductive member has a cooling-water flow path inside thereof.
